(19) United States
(12) Patent Application Publication
(10) Pub. No.: US 2025/0004045 A1
(43) Pub. Date: Jan. 2, 2025

(54) SEMICONDUCTOR PACKAGE AND METHOD FOR IDENTIFYING INTEGRATED CIRCUIT LAYERS IN STACK

(71) Applicant: AP MEMORY TECHNOLOGY CORPORATION, HSINCHU COUNTY (TW)

(72) Inventors: WENLIANG CHEN, HSINCHU COUNTY (TW); LIN MA, BEAVERTON, OR (US)

(21) Appl. No.: 18/757,416

(22) Filed: Jun. 27, 2024

Related U.S. Application Data
(60) Provisional application No. 63/511,432, filed on Jun. 30, 2023.

(51) Int. Cl. G01R 31/28; G01R 15/04; G01R 19/00; H01L 23/48; H01L 25/065; H10B 80/00

(52) U.S. Cl. CPC G01R 31/2896; G01R 15/04; G01R 19/0038; H01L 23/481; H01L 25/0657; H10B 80/00

(57) ABSTRACT

A semiconductor package includes a plurality of integrated circuit (IC) substrates and a conductive structure. The IC substrates are stacked one above another. The conductive structure penetrates through the IC substrates. Each of the IC substrates includes an identification circuit coupled to the conductive structure. Each identification circuit is configured to identify a corresponding IC substrate by receiving an input signal from the conductive structure and accordingly generating an identifier of the corresponding IC substrate.

### PRIORITY CLAIM AND CROSS-REFERENCE

The present application claims priority to U.S. Provisional Patent Application No. 63/511,432, filed on Jun. 30, 2023, which is incorporated by reference herein in its entirety.

### BACKGROUND

The present disclosure relates to semiconductor packages, and more particularly, to a semiconductor package and a method for identifying integrated circuit substrates in a stack.

To further enhance system performance, integration density, signal transmission speed, and data processing capacity, an increasing number of electronic products are adopting three-dimensional (3D) semiconductor packaging technology. This technology includes chip-on-chip stacking, chip-on-wafer (CoW) stacking, and wafer-on-wafer (WoW) stacking. For example, wafer-on-wafer stacking allows for the vertical connections between of multiple wafers, achieving the vertical integration of multiple chips. When applied in high-performance computing, wafer-on-wafer stacking can utilize vertical integration of processor chips and memory chips to enhance computing speed and data throughput. When applied in memory devices, wafer-on-wafer stacking can increase storage density and read/write speeds.

### SUMMARY

The described embodiments provide a semiconductor package and a method for identifying integrated circuit substrates in a stack.

Some embodiments described herein may include a semiconductor package. The semiconductor package includes a plurality of integrated circuit (IC) substrates and a conductive structure. The IC substrates are stacked one above another. The conductive structure penetrates through the IC substrates. Each of the IC substrates includes an identification circuit coupled to the conductive structure. Each identification circuit is configured to identify a corresponding IC substrate by receiving an input signal from the conductive structure and accordingly generating an identifier of the corresponding IC substrate.

Some embodiments described herein may include a method for identifying integrated circuit (IC) substrates in a stack. The method includes: when each of the IC substrates is in a non-selectable state, turning a first IC substrate of the IC substrates from the non-selectable state to a selectable state by assigning a first identifier to the first IC substrate; applying an input signal to a conductive structure penetrating through the IC substrates in the stack; and identifying a second IC substrate of the IC substrates by referring to the input signal to generate a second identifier, wherein the second IC substrate is adjacent to the first IC substrate.

With the use of the proposed identification scheme, each layer in a chip/wafer stack can be assigned a unique identifier according to a physical spatial relationship between the stacked layers. The proposed identification scheme can individually identify the stacked layers according to their identifiers, thereby ensuring correct implementation of system functions and realizing precise testing and failure analysis.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary semiconductor package in accordance with some embodiments of the present disclosure.

FIG. 2A is a diagram illustrating an implementation of the IC substrates shown in FIG. 1 in accordance with some embodiments of the present disclosure.

FIG. 2B is a diagram illustrating another implementation of the IC substrates shown in FIG. 1 in accordance with some embodiments of the present disclosure.

FIG. 3A to FIG. 3C are diagrams illustrating the placement of the control circuit arranged for controlling the identification circuits shown in FIG. 1 in accordance with some embodiments of the present disclosure.

FIG. 4 is a diagram illustrating an implementation of the semiconductor package 100 shown in FIG. 1 in accordance with some embodiments of the present disclosure.

FIG. 5 illustrates an implementation of the identification circuit shown in FIG. 4 in accordance with some embodiments of the present disclosure.

FIG. 6 is a diagram illustrating another implementation of the semiconductor package shown in FIG. 1 in accordance with some embodiments of the present disclosure.

FIG. 7 is a diagram illustrating another implementation of the semiconductor package 100 in FIG. 1 in accordance with some embodiments of the present disclosure.

FIG. 8 illustrates an implementation of the identification circuit shown in FIG. 7 in accordance with some embodiments of the present disclosure.

FIG. 9 is a diagram illustrating another implementation of the semiconductor package 100 shown in FIG. 1 in accordance with some embodiments of the present disclosure.

FIG. 10 is a diagram illustrating another implementation of the semiconductor package 100 shown in FIG. 1 in accordance with some embodiments of the present disclosure.

FIG. 11 is a flow chart of an exemplary method for identifying IC substrates in a stack in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In semiconductor structures that utilize 3D packaging, stacked chips/wafers may correspond to the same function. As it may be difficult to distinguish between these chips/wafers based on their electrical characteristics and operation, attempting to access one chip might inadvertently lead to accessing another chip with the same function. For example, addressing the memory circuits in one chip layer might mistakenly address the memory circuits in another chip layer. As another example, attempting to perform failure analysis (FA) on circuits in one chip layer might unintentionally result in perform failure analysis on circuits in another chip layer.

The present disclosure provides exemplary identification scheme capable of identifying individual wafers/chips in a stack of wafers/chips. The proposed identification scheme can utilize an identification circuit built within each wafer/chip to assign a unique identifier to the wafer/chip. For example, the identification circuit can be configured for signaling between neighboring wafers/chips, thereby generating a unique identifier for a corresponding wafer/chip. As another example, the identification circuit can generate a unique identifier for a corresponding wafer/chip by referring signals transmitted via a shared conductive structure penetrating the stacked wafer/chips.

In some embodiments, the proposed identification scheme can leverage the physical spatial relationship between the stacked chip/wafer layers to provide each layer with a unique identifier. Note that the proposed identification scheme can be applied to not only stacked chip/wafer with the same structure/function, but also stacked chip/wafer with different structures/functions. With the use of the proposed identification scheme, chip/wafer layers in a stack can be individually identified, thereby ensuring correct implementation of system functions and realizing precise testing and failure analysis. Further description is provided below.

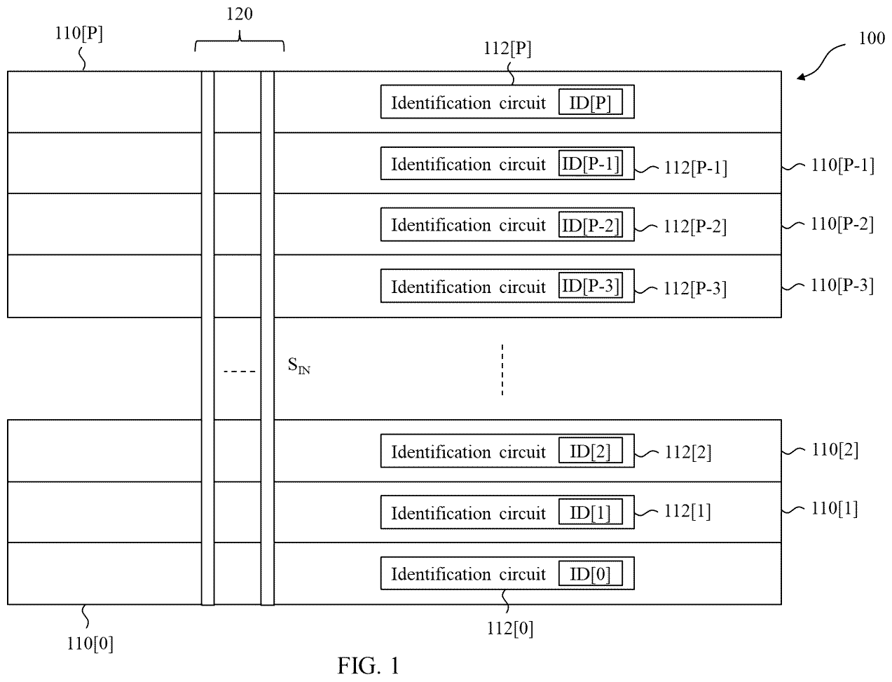

FIG. 1 is a diagram illustrating an exemplary semiconductor package in accordance with some embodiments of the present disclosure. The semiconductor package 100 includes, but is not limited to, a plurality of integrated circuit (IC) substrates 110[0]-110[P] (where P is greater than 1) and a conductive structure 120. The IC substrates 110[0]-110[P] are stacked one above another, and can be (P+1) stacked wafers, dies or chips. The conductive structure 120 penetrates through the IC substrates 110[0]-110[P] to make them electrically interconnected. The conductive structure 120 may include a plurality of through-substrate vias (TSVs) or through-silicon vias (TSVs).

Each IC substrate may include an identification circuit (i.e. one of the identification circuits 112[0]-112[P]), which is configured for identifying the IC substrate. In the present embodiment, the identification circuit 112[i] (i=0, 1, . . . , P) can generate an identifier ID[i] corresponding to the IC substrate 110[i]. The identifier ID[i] can provide information for identifying or labeling the IC substrate 110[i]. By way of example but not limitation, the identifier ID[i] can be a multi-bit signal or data that corresponds to an IC substrate address directed to the IC substrate 110[i]. As another example, the identifier ID[i] can be a multi-bit signal or data that uniquely label the IC substrate 110[i]. The identifiers for different IC substrates are distinct, meaning that the identification circuit 112[i] can generate a unique identifier for the IC substrate 110[i].

In addition, an order of the identifiers ID[0]-ID[P] can match a spatial arrangement order of the IC substrates 110[0]-110[P]. By way of example but not limitation, the values/patterns indicated by the identifiers ID[0]-ID[P] may show an ascending or descending relationship to represent the spatial configuration of the sequentially stacked IC substrates 110[0]-110[P].

In some embodiments, part or all of the IC substrates 110[0]-110[P] can be identical to each other. For example, IC substrates that are identical to each other can have the same core structure/function. As another example, IC substrates that are identical to each other can be memory IC substrates such as dynamic random-access memory (DRAM) having the same capacity or density. The identical IC substrates can be accessed through the shared conductive structure 120. With the use of the identifiers that are obtained by the identification circuits built in the IC substrates, an interest of IC substrate within the stacked IC substrates, which are difficult to distinguish electrically based on their structures/functions, can be accurately identified and accessed.

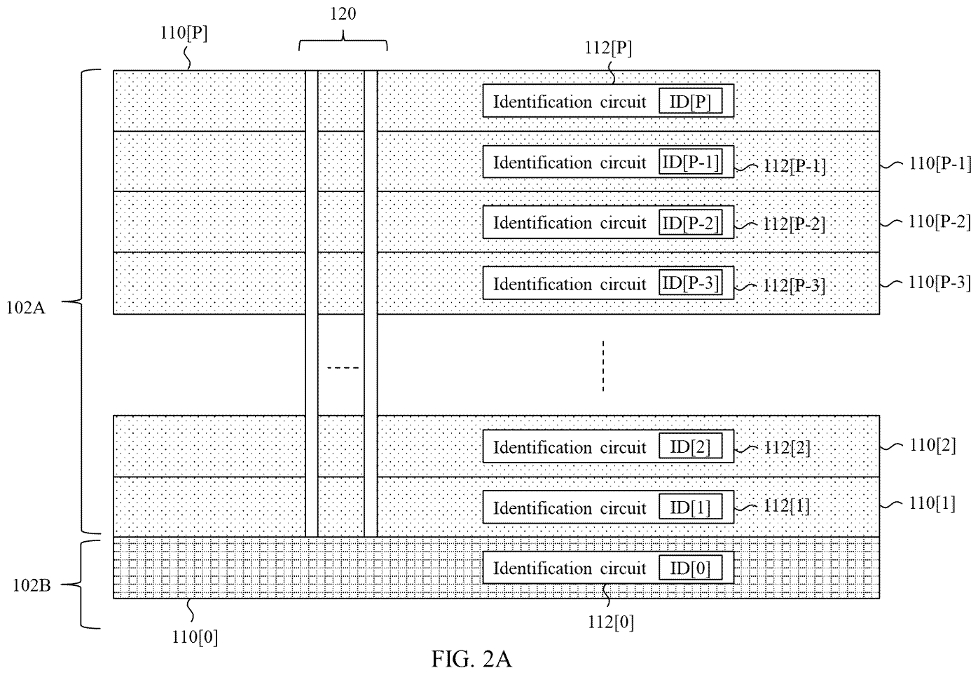

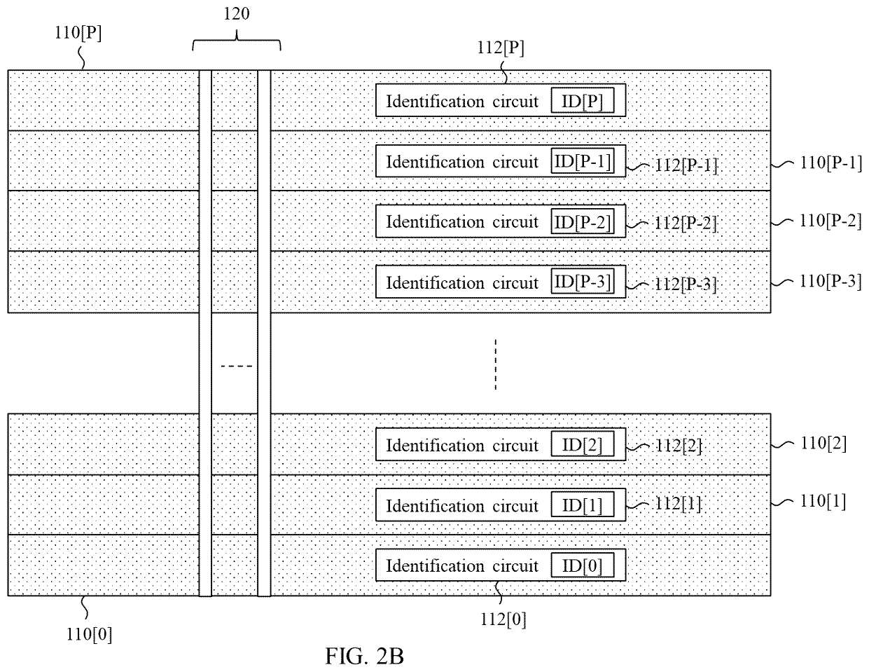

FIG. 2A is a diagram illustrating an implementation of the IC substrates 110[0]-110[P] shown in FIG. 1 in accordance with some embodiments of the present disclosure. In the present embodiment, the IC substrates 110[1]-110[P] are identical to each other, while the IC substrate 110[0] is non-identical to the IC substrates 110[1]-110[P]. For example, the IC substrates 110[1]-110[P] have the same structure/function, while the IC substrate 110[0] has a structure/function different from that of each of the IC substrates 110[1]-110[P]. Each of the IC substrates 110[1]-110[P] can be referred to as an identical layer (i.e. an identical wafer/die/chip), and the IC substrates 110[1]-110[P] can be regarded as an IC structure 102A having multiple identical layers. The IC substrate 110[0] can be referred to as a non-identical layer (i.e. a non-identical wafer/die/chip), and the IC substrate 110[0] can be regarded as at least a portion of an IC structure 102B that includes at least one non-identical layer. In some embodiments, more than one of the IC substrates 110[1]-110[P] can be non-identical to the other IC substrates.

By way of example but not limitation, the IC substrates 110[1]-110[P] can be implemented as memory IC substrates, each containing at least one memory such as dynamic random-access memory (DRAM); the IC substrate 110[0] can be implemented as a logic IC substrate that contains processor(s), such as a central processing units (CPU) and/or a graphics processing unit (GPU). In some embodiments, the identifier of the non-identical layer (e.g., the identifier ID[0] of the IC substrate 110[0]) may be determined first; the identifiers of the identical layers can be generated according to the identifier of the non-identical layer and the spatial arrangement of the identical layers. Note that the is not intended to limit the scope of the present disclosure.

FIG. 2B is a diagram illustrating another implementation of the IC substrates 110[0]-110[P] shown in FIG. 1 in accordance with some embodiments of the present disclosure. In the present embodiment, the IC substrates 110[0]-110[P] are identical to each other, or have the same structure/function. The IC substrates 110[0]-110[P] can be regarded as identical layers (i.e. identical wafers/dies/chips). By way of example but not limitation, the IC substrates 110[0]-110[P] can be implemented as memory IC substrates containing memories such as DRAMs. In some embodiments, the identifier of one of the identical layers (e.g. the identifier ID[0]/ID[P] of the outermost IC substrate 110[0]/110[P] in the stack) may be determined first; the identifiers of the identical layers can be generated according to the determined identifier and the spatial arrangement of the identical layers. Note that this is not intended to limit the scope of the present disclosure.

Referring again to FIG. 1, each identification circuit can be coupled to the conductive structure 120, and configured to identify a corresponding IC substrate by receiving an input signal S_{IN} from the conductive structure 120 and accordingly generating an identifier of the corresponding IC substrate.

By way of example but not limitation, the input signal S_{IN} can be an address input provided for selecting an IC substrate, which is assigned a unique identifier corresponding to an address indicated by input signal S_{IN}. As another example, the input signal S_{IN} can be a voltage signal, which is applied to each IC substrate for determining which IC substrate to be identified.

In the present embodiment, the input signal S_{IN} can have different signal values/patterns, which can correspond to the contents of the identifiers ID[0]-ID[P] respectively. In some embodiments, the identification circuits 112[0]-112[P] may sequentially generate the identifiers ID[0]-ID[P]. For example, the identification circuit 112[0] can generate the identifier ID[0] according to the input signal S_{IN} with a first signal value, the identification circuit 112[1] can generate the identifier ID[1] according to the input signal S_{IN} with a second signal value, and so on. In other words, the identification circuits 112[0]-112[P] can be configured to generate respective identifiers ID[0]-ID[P] sequentially in a spatial arrangement order of the IC substrates 110[0]-110[P].

Additionally or alternatively, in some embodiments where the input signal S_{IN} can indicate an address corresponding to an identifier of an IC substrate, an identification circuit located in the IC substrate can send a stimulus signal to another identification circuit located in another IC substrate, thereby enabling the another identification circuit to refer to the input signal S_{IN} to generate a corresponding identifier. For example, the identification circuit 112[0] can send a stimulus signal to the neighboring identification circuit 112[1], thereby enabling the identification circuit 112[1] to refer to the input signal S_{IN} to generate the identifier ID[1].

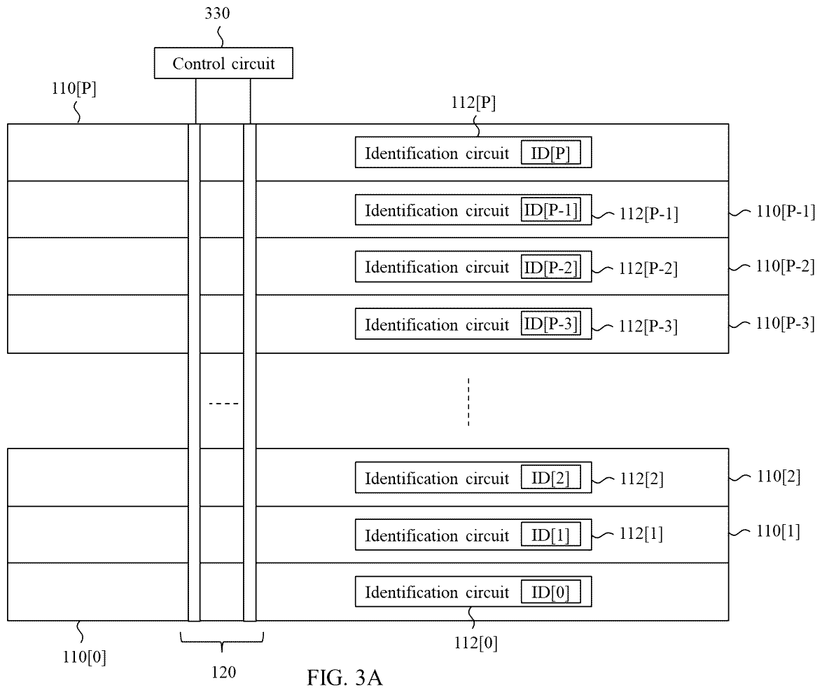

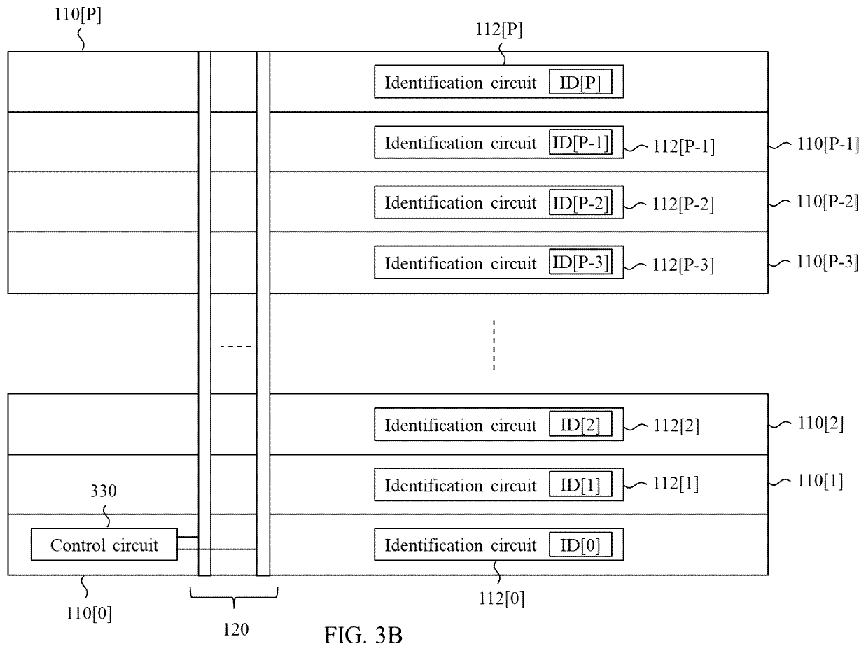

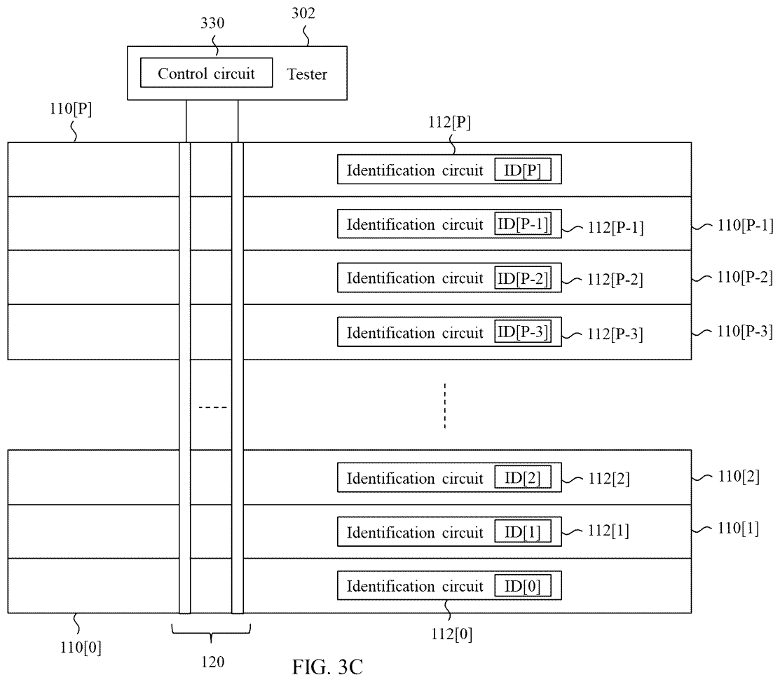

The identification circuits 112[0]-112[P] can be controlled by a control circuit, which can be located either outside or inside the IC substrates 110[0]-110[P]. FIG. 3A to FIG. 3C are diagrams illustrating the placement of the control circuit arranged for controlling the identification circuits 112[0]-112[P] shown in FIG. 1 in accordance with some embodiments of the present disclosure. Referring firstly to FIG. 3A, the identification circuits 112[0]-112[P] can be controlled by the control circuit 330 located outside the IC substrates 110[0]-110[P]. The control circuit 330 is coupled to the conductive structure 120 to generate signals involved in the operations of the identification circuits 112[0]-112[P], such as the input signal S_{IN}. In the embodiment shown in FIG. 3A, the control circuit 330 can be included within the semiconductor package 100.

Referring to FIG. 3B, the identification circuits 112[0]-112[P] can be controlled by the control circuit 330 located in the IC substrate 110[0]. The control circuit 330, coupled to the conductive structure 120, is configured to generate signals involved in the operations of the identification circuits 112[0]-112[P], such as the input signal S_{IN}. The IC substrate 110[0] can be either a non-identical layer or an identical layer. In other words, the control circuit 330 can be built in a non-identical layer or an identical layer.

Referring to FIG. 3C, the identification circuits 112[0]-112[P] can be controlled by the control circuit 330 located within a tester 302. The tester 302 can be an IC testing system or a semiconductor testing system located outside the semiconductor package 100. The control circuit 330, coupled to the conductive structure 120, is configured to generate signals involved in the operations of the identification circuits 112[0]-112[P], such as the input signal S_{IN}. The control circuits 330 shown in FIG. 3A to FIG. 3C can be implemented as logic controllers, logic circuits, application-specific integrated circuits (ASICs), or other types of control circuits.

To facilitate understanding of the present disclosure, some implementations are given below for further description of the proposed wafer/chip identification scheme. However, the implementations are provided for illustrative purposes, and are not intended to limit the scope of the present disclosure. Those skilled in the art can appreciate that other implementations employing the architecture shown in FIG. 1 to identify individual wafers/dies/chips in a stack are within the scope of the present disclosure.

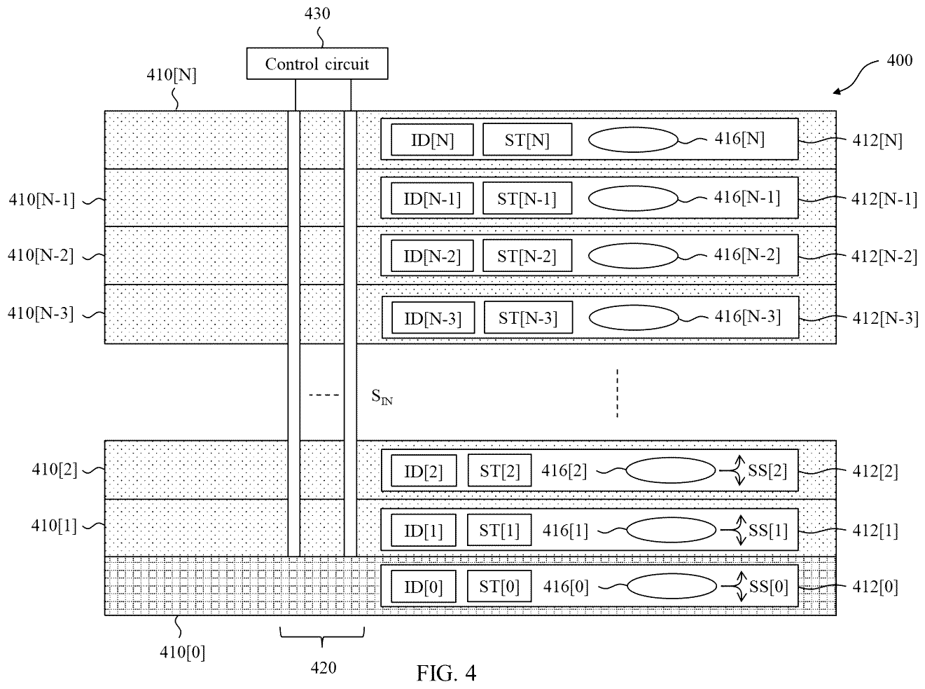

FIG. 4 is a diagram illustrating an implementation of the semiconductor package 100 shown in FIG. 1 in accordance with some embodiments of the present disclosure. In the present embodiment, the semiconductor package 400 may include IC substrates 410[0]-410[N] (where N is greater than 1) stacked one above another, and a conductive structure 420. The IC substrates 410[0]-410[N] can be substantially similar/identical to the IC substrates 110[0]-110[P] shown in FIG. 1, or can serve as examples of the IC substrates 110[0]-110[P] shown in FIG. 1. The IC substrates 410[1]-410[N] can be implemented as identical layers, and IC substrate 410[0] can be implemented as a non-identical layer. The conductive structure 420 can be substantially similar/identical to the conductive structure 120 shown in FIG. 1, or can serve as an example of the conductive structure 120 shown in FIG. 1. The IC substrates 410[0]-410[N] include identification circuits 412[0]-412[N] respectively, which can be substantially similar/identical to the identification circuits 112[0]-112[P] shown in FIG. 1, or can serve as examples of the identification circuits 112[0]-112[P] shown in FIG. 1.

The identification circuits 412[0]-412[N] can utilize wireless coupling to identify the IC substrates 410[1]-410[N]. In the present embodiment, each identification circuit may include a coupling circuit (e.g., one of the coupling circuits 416[0]-416[N]), which can be configured to send and receive stimulus signals. The stimulus signals can be sent and received via wireless coupling (e.g. inductive or capacitive coupling) between the coupling circuits (or the identification circuits) of adjacent IC substrates. For example, each coupling circuit can be implemented as an inductive coupling circuit (e.g. an inductive element or an induction coil), an induced voltage produced by the inductive coupling circuit can serve as a stimulus signal, and the coupling circuits 416[0]-416[N] can act as an inductive coupling chain. As another example, each coupling circuit can be implemented as a capacitive coupling circuit (e.g. a capacitive element or a planar electrode), an induced current produced by the capacitive coupling circuit can serve as a stimulus signal, and the coupling circuits 416[0]-416[N] acting as a capacitive coupling chain.

Through interaction between adjacent coupling circuits, the identification circuits 412[0]-412[N] can generate identifiers ID[0]-ID[N], which can indicate the spatial arrangement relationship between the IC substrates 410[0]-410[N]. For example, a stimulus signal sent from a first coupling circuit can enable a second coupling circuit that is adjacent to the first coupling circuit to generate an induced signal; an identification circuit including the second coupling circuit can generate an identifier accordingly. Other coupling circuits that are not adjacent to the first coupling circuit will not (or almost will not) respond to or receive the stimulus signal sent from the first coupling circuit. Thus, two identification circuits which generate respective identifiers in sequence can be located in two adjacent IC substrates. In some examples where the identifiers ID[0]-ID[N] are presented in an ascending or descending order, two adjacent identifiers can correspond to two adjacent IC substrates.

In the present embodiment, each identification circuit can be controlled by a control circuit 430 located outside the IC substrates 410[0]-410[N]; a coupling circuit of the identification circuit can be enabled by the control circuit 430 to generate a stimulus signal. The control circuit 430 can be a logic controller located inside the semiconductor package 400, or a logic controller within a tester outside the semiconductor package 400.

In operation, the control circuit 430 may firstly reset the IC substrates 410[1]-410[N] to a non-selectable state, and set the identifier ID[0] of the IC substrate 410[0] as the data ID0, making the IC substrate 410[0] selectable. In the present embodiment, if an IC substrate is in a selectable state, it can represent that the IC substrate is selectable or has been identified; if an IC substrate is in a non-selectable state, it can represent that the IC substrate is not selectable or has not been identified. When an identifier of an IC substrate is generated, the IC substrate can be identified.

For example, the identification circuit 412[i] (i=0, 1, . . . , N) can store or register state information ST[i], which can indicate whether the IC substrate 410[i] is in a selectable state or whether the IC substrate 410[i] has been identified. The control circuit 430 can set the state information ST[1]-ST[N] to indicate that the IC substrates 410[1]-410[N] are non-selectable. In addition, the control circuit 430 can assign an address signal indicative of the data ID0 to the identification circuit 412[0], thereby setting the identifier ID[0] as the data ID0 and setting the state information ST[0] to indicate that the IC substrate 410[0] is selectable.

Next, the control circuit 430 can select the IC substrate 410[0], and enable the IC substrate 410[0] to send a stimulus signal SS[0]. The adjacent IC substrate 410[1] can receive the stimulus signal SS[0], and accordingly generate the identifier ID[1] and set the IC substrate 410[1] to a selectable state.

For example, the control circuit 430 can send the input signal S_{IN} that indicates an address corresponding to the identifier ID[0] to select the IC substrate 410[0], and enable the coupling circuit 416[0] of the identification circuit 412[0] to send the stimulus signal SS[0]. The adjacent identification circuit 412[1] can receive the stimulus signal SS[0], and set the identifier ID[1] as the data ID1 (e.g. the data ID0 plus a predetermined value or address offset) according to the input signal S_{IN}. Other identification circuits that are not adjacent to the identification circuit 412[0] will not (or almost will not) respond to the stimulus signal SS[0]. Additionally, the identification circuit 412[1] can set the state information ST[1] according to the stimulus signal SS[0]; the state information ST[1] can indicate that the IC substrate 410[1] is selectable.

After the identifier ID[1] is generated, the control circuit 430 can select the IC substrate 410[1] and enable the identification circuit 412[1] to generate a stimulus signal SS[1]. The adjacent IC substrate 410[2] can receive the stimulus signal SS[1], and accordingly generate the identifier ID[2] and set the IC substrate 410[2] to a selectable state.

For example, the control circuit 430 can send the input signal S_{IN} that indicates an address corresponding to the identifier ID[1] to select the IC substrate 410[1], and enable the coupling circuit 416[1] of the identification circuit 412[1] to send the stimulus signal SS[1]. The adjacent identification circuit 412[2] can receive the stimulus signal SS[1], and set the identifier ID[2] as the data ID2 (e.g. the data ID1 plus a predetermined value or address offset) according to the input signal S_{IN}. In addition, the identification circuit 412[2] can set the state information ST[2] according to the stimulus signal SS[1]; the state information ST[2] can indicate that the IC substrate 410[2] is selectable.

Note that the adjacent identification circuit 412[0], which is already in a selectable state or has been identified, will not (or almost will not) respond to the stimulus signal SS[1]. The identifier ID[0] of the IC substrate 410[0] can remain unchanged when the stimulus signal SS[1] is sent to the IC substrate 410[0]. In other words, the identification circuit 412[0] can ignore the stimulus signal SS[1] according to the state information ST[0] which indicates that the IC substrate 410[0] has been identified. The identifier ID[0] of the IC substrate 410[0] can remain unchanged from the data ID0.

Similarly, after the identifier ID[2] is generated, the control circuit 430 can select IC substrate 410[2] and enable the identification circuit 412[2] to generate a stimulus signal SS[2]. The adjacent IC substrate 410[3] can receive the stimulus signal SS[2], and accordingly generate the identifier ID[3] and set the IC substrate 410[3] to a selectable state.

For example, the control circuit 430 can send the input signal S_{IN} that indicates an address corresponding to the identifier ID[2] to select the IC substrate 410[2], and enable the coupling circuit 416[2] of the identification circuit 412[2] to send the stimulus signal SS[2]. The adjacent identification circuit 412[3] can receive the stimulus signal SS[2], and set the identifier ID[3] as the data ID3 (e.g. the data ID2 plus a predetermined value or address offset) according to the input signal S_{IN}. In addition, the identification circuit 412[3] can set the state information ST[3] according to the stimulus signal SS[2]; the state information ST[3] can indicate that the IC substrate 410[3] is selectable. Note that the adjacent identification circuit 412[1], which is already in a selectable state or has been identified, will not (or almost will not) respond to the stimulus signal SS[2]. The identifier ID[1] of the IC substrate 410[1] can remain unchanged when the stimulus signal SS[2] is sent to the IC substrate 410[1]. In other words, the identification circuit 412[1] can ignore the stimulus signal SS[2] according to the state information ST[1] which indicates that the IC substrate 410[1] has been identified. The identifier ID[1] of the IC substrate 410[1] can remain unchanged from the data ID1.

After the respective identifiers ID[0]-ID[N] have been stored in the IC substrates 410[0]-410[N], the control circuit 430 can individually select the IC substrates 410[0]-410[N] according to the identifiers ID[0]-ID[N].

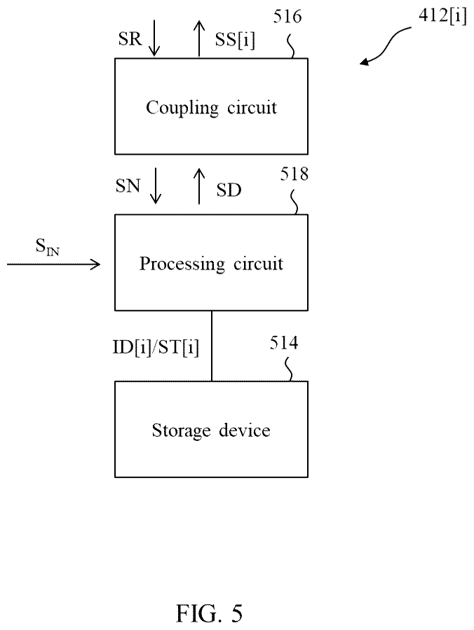

FIG. 5 illustrates an implementation of the identification circuit 412[i] (i=0, 1, . . . , N) shown in FIG. 4 in accordance with some embodiments of the present disclosure. The identification circuit 412[i] can include, but is not limited to, a storage device 514, a coupling circuit 516 and a processing circuit 518. The storage device 514 is configured to store the state information ST[i] and the identifier ID[i] of the IC substrate 410[i] shown in FIG. 4. The storage device 514 can be implemented using volatile or non-volatile storage devices. The coupling circuit 516 is configured to receive a drive signal SD, and generate the stimulus signal SS[i] according to the drive signal SD. The processing circuit 518 is coupled to the storage device 514 and the coupling circuit 516. The processing circuit 518 can be configured to selectively generate the drive signal by determining whether the input signal S_{IN} indicates an address corresponding to the identifier ID[i] of the IC substrate 410[i]. For example, when the input signal S_{IN} indicates the address corresponding to the identifier ID[i], the processing circuit 518 can generate the drive signal SD; when the input signal S_{IN} does not match the identifier ID[i], the processing circuit 518 will not generate the drive signal SD.

Additionally or alternatively, the coupling circuit 516 is configured to receive a stimulus signal SR, and generate an induced signal SN according to the stimulus signal SR. When the state information ST[i] indicates a non-selectable state, the processing circuit 518 is configured to receive the induced signal SN, refer to the input signal S_{IN} to generate the identifier ID[i], and update the state information ST[i] to indicate that the IC substrate 410[i] is selectable. Note that when the state information ST[i] indicates that the IC substrate 410[i] is selectable, the processing circuit 518 will not respond to the induced signal SN.

Consider an example where the identification circuit 412[1] shown in FIG. 4 is implemented using the architecture shown in FIG. 5 (i.e. i=1). Referring to FIG. 5 and also to FIG. 4, when the control circuit 430 is configured to send the input signal S_{IN} (which indicates an address corresponding to the identifier ID[0]) to select the IC substrate 410[0], the processing circuit 518 can determine that an address indicated by the input signal S_{IN} does not match the identifier ID[1] read from the storage device 514. Thus, the processing circuit 518 does not generate the drive signal SD. When the IC substrate 410[0] is selected and sends the stimulus signal SS[0], the coupling circuit 516 can generate the induced signal SN according to the induced signal SR (i.e. the stimulus signal SS[0] sent from the IC substrate 410[0]). The processing circuit 518 can receive the induced signal SN, and read the state information ST[1] (which indicates that the IC substrate 410[1] is non-selectable) from the storage device 514. The processing circuit 518 can refer to the input signal S_{IN} to generate the identifier ID[1], and update the state information ST[1] to indicate that the IC substrate 410[1] is selectable.

Consider another example where the identification circuit 412[0] shown in FIG. 4 is implemented using the architecture shown in FIG. 5 (i.e., i=0). When the control circuit 430 is configured to send the input signal S_{IN} (which indicates an address corresponding to the identifier ID[0]) to select the IC substrate 410[0], the processing circuit 518 can determine that an address indicated by the input signal S_{IN} corresponds to the identifier ID[0] (read from the storage device 514) and that the state information ST[0] (read from the storage device 514) indicates the selectability of the IC substrate 410[0]. Thus, the processing circuit 518 can generate the drive signal SD. In addition, when the control circuit 430 is configured to send the input signal S_{IN} (which indicates an address corresponding to the identifier ID[1]) to thereby enable the IC substrate 410[1] to generate the stimulus signal SS[1], the coupling circuit 516 can generate the induced signal SN according to the induced signal SR (i.e. the stimulus signal SS[1] sent from the IC substrate 410[1]). As the state information ST[0] read from the storage device 514 indicates that the IC substrate 410[0] is selectable, the processing circuit 518 will not respond to the induced signal SN. In other words, the processing circuit 518 will not change/update the identifier ID[0].

As those skilled in the art can appreciate that the architecture shown in FIG. 5 can be applied to each identification circuit shown in FIG. 4, similar description is omitted here for brevity.

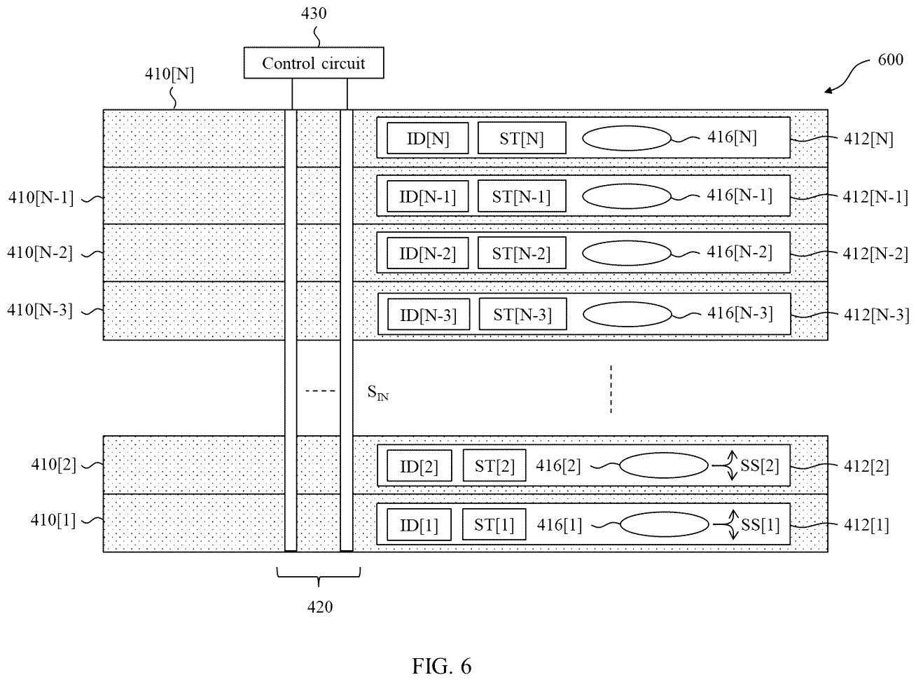

FIG. 6 is a diagram illustrating another implementation of the semiconductor package 100 shown in FIG. 1 in accordance with some embodiments of the present disclosure. The structure of the semiconductor package 600 is substantially identical to that of the semiconductor package 400 shown in FIG. 4 except that the stacked IC substrates of the semiconductor package 600 are implemented as identical layers. In the present embodiment, the semiconductor package 600 includes the IC substrates 410[1]-410[N] and the conductive structure 420 shown in FIG. 4.

In operation, the control circuit 430 may firstly reset the IC substrates 410[2]-410[N] to a non-selectable state, and set the identifier ID[1] of the IC substrate 410[1] as the data ID1, making the IC substrate 410[1] selectable.

For example, the control circuit 430 can set the state information ST[2]-ST[N] to indicate that the IC substrates 410[2]-410[N] are non-selectable, and set the state information ST[1] to indicate that the IC substrate 410[1] is selectable. In addition, the control circuit 430 can set the identifier ID[1] as the data ID1 according to the input signal S_{IN}. The input signal S_{IN} can include, but is not limited to, an address input indicative of the data ID1.

Next, the control circuit 430 can select the IC substrate 410[1], and enable the IC substrate 410[1] to send a stimulus signal SS[1]. The adjacent IC substrate 410[2] can receive the stimulus signal SS[1], and accordingly generate the identifier ID[2] and set the IC substrate 410[2] to a selectable state.

For example, the control circuit 430 can send the input signal S_{IN} that indicates an address corresponding to the identifier ID[1] to select the IC substrate 410[1], and enable the coupling circuit 416[1] of the identification circuit 412[1] to send the stimulus signal SS[1]. The adjacent identification circuit 412[2] can receive the stimulus signal SS[1], and set the identifier ID[2] as the data ID2 (e.g. the data ID1 plus a predetermined value or address offset) according to the input signal S_{IN}. In addition, the identification circuit 412[2] can set the state information ST[2] according to the stimulus signal SS[1]; the state information ST[2] can indicate that the IC substrate 410[2] is selectable.

After the identifier ID[2] is generated, the control circuit 430 can select the IC substrate 410[2] and enable the identification circuit 412[2] to generate a stimulus signal SS[2]. The adjacent IC substrate 410[3] can receive the stimulus signal SS[2], and accordingly generate the identifier ID[3] and set the IC substrate 410[3] to a selectable state.

For example, the control circuit 430 can send the input signal S_{IN} that indicates an address corresponding to the identifier ID[2] to select the IC substrate 410[2], and enable the coupling circuit 416[2] of the identification circuit 412[2] to send the stimulus signal SS[2]. The adjacent identification circuit 412[3] can receive the stimulus signal SS[2], and set the identifier ID[3] as the data ID3 (e.g. the data ID2 plus a predetermined value or address offset) according to the input signal S_{IN}. In addition, the identification circuit 412[3] can set the state information ST[3] according to the stimulus signal SS[2]; the state information ST[3] can indicate that the IC substrate 410[3] is selectable. The identification circuit 412[1] that is already in a selectable state will not (or almost will not) respond to the stimulus signal SS[2]. The identifier ID[1] of the IC substrate 410[1] is not modified by the stimulus signal SS[2] when the IC substrate 410[1] has been identified.

As those skilled in the art can appreciate that the operation of the semiconductor package 600 after reading the above paragraphs directed to FIG. 1 to FIG. 5, further description is omitted here for brevity.

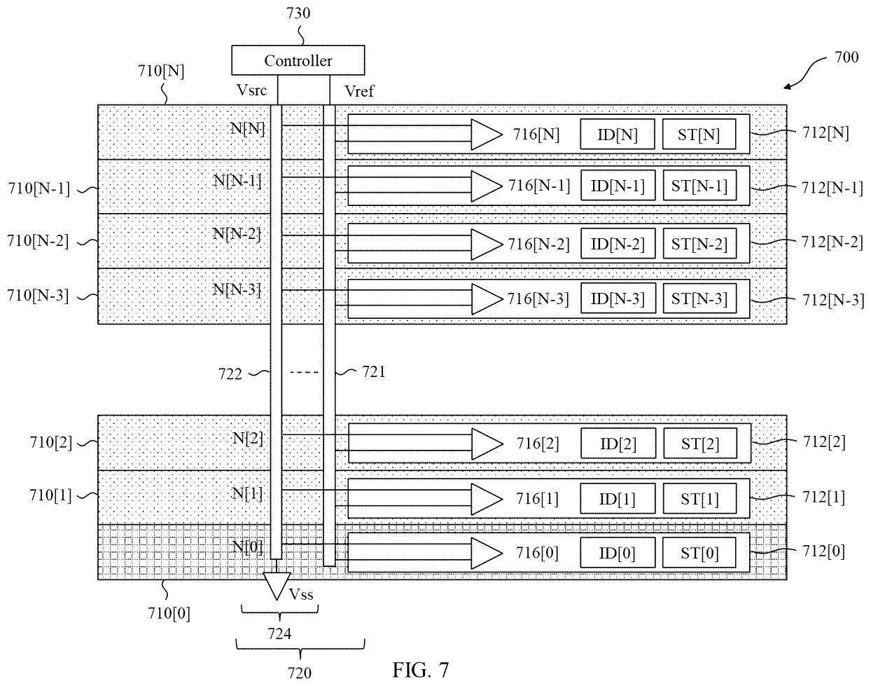

FIG. 7 is a diagram illustrating another implementation of the semiconductor package 100 shown in FIG. 1 in accordance with some embodiments of the present disclosure. In the present embodiment, the semiconductor package 700 may include IC substrates 710[0]-710[N] (where N is greater than 1) stacked one above another, and a conductive structure 720. The IC substrates 710[0]-710[N] can be substantially similar/identical to the IC substrates 110[0]-110[P] shown in FIG. 1, or can serve as examples of the IC substrates 110[0]-110[P] shown in FIG. 1. The IC substrates 710[1]-710[N] can be implemented as identical layers, and IC substrate 710[0] can be implemented as a non-identical layer. The conductive structure 720 can be substantially similar/identical to the conductive structure 120, or can serve as an example of the conductive structure 120 shown in FIG. 1. The IC substrates 710[0]-710[N] include identification circuits 712[0]-712[N] respectively, which can be substantially similar/identical to the identification circuits 112[0]-112[P], or can serve as examples of the identification circuits 112[0]-112[P] shown in FIG. 1.

The identification circuits 712[0]-712[N] can utilize voltage division to identify the IC substrates 710[0]-710[N]. In the present embodiment, the conductive structure 720 includes conductive paths 721 and 722 penetrating through the IC substrates 710[1]-710[N]. Each of the conductive paths 721 and 722 may be a common through-substrate via shared by the identification circuits 712[0]-712[N]. The reference voltage Vref applied to the conductive path 721 can serve as an example of the input signal S_{IN} shown in FIG. 1. In addition, two ends of the conductive path 722 are connected to different electric potentials to form a voltage divider 724 with nodes N[0]-N[N], and a segment of the conductive path 722 between two adjacent nodes serves as a resistive element in the voltage divider 724. In the example of FIG. 7, two ends of the conductive path 722 are respectively coupled to a predetermined voltage Vsrc (a source voltage applied to the IC substrate 710[N]) and a predetermined voltage Vss (a reference voltage applied to IC substrate 710[0]).

The identification circuits 712[0]-712[N] are coupled to the nodes N[0]-N[N] respectively, and each identification circuit is configured to generate an identifier of a corresponding IC substrate by comparing the reference voltage Vref with a node voltage at a corresponding node. The node voltage is a proportionally divided voltage between the predetermined voltage Vsrc and the predetermined voltage Vss. The identification circuits 712[0]-712[N] can generate the identifiers ID[0]-ID[N] by detecting their respective divided voltages. The identifiers ID[0]-ID[N] can indicate the spatial arrangement relationship between the IC substrates 710[0]-710[N].

For example, each identification circuit may include a comparator (i.e. one of the comparators 716[0]-716[N]). A first input terminal and a second input terminal of each comparator are coupled to a corresponding node and the reference voltage Vref, respectively. By adjusting the reference voltage Vref, the voltage levels at the nodes N[0]-N[N] coupled to the identification circuits 712[0]-712[N] can be detected, and the identifiers ID[0]-ID[N] can be generated accordingly. As the voltage levels at the nodes N[0]-N[N] can show an ascending relationship, the values/patterns indicated by identifiers ID[0]-ID[N] can indicate a spatial arrangement relationship between the IC substrates 712[0]-712[N].

In the present embodiment, each identification circuit can be controlled by a control circuit 730 located outside the IC substrates 710[0]-710[N], and both the predetermined voltage Vsrc and the reference voltage Vref can be provided by the control circuit 730. The control circuit 730 can be a logic controller located in the semiconductor package 700, or a logic controller within a tester outside the semiconductor package 700.

In operation, the control circuit 730 may firstly reset the IC substrates 710[1]-710[N] to a non-selectable state, and set the identifier ID[0] of the IC substrate 710[0] as the data ID0, making set the IC substrate 710[0] selectable.

For example, the identification circuit 712[i] (i=0, 1, . . . , N) can store or register state information ST[i], which can indicate whether the IC substrate 710[i] is in a selectable state or whether the IC substrate 710[i] has been identified. The control circuit 730 can set the state information ST[1]-ST[N] to indicate that the IC substrates 710[1]-710[N] are non-selectable. In addition, the control circuit 730 can assign an address signal indicative of the data ID0 to the identification circuit 712[0], thereby setting the identifier ID[0] as the data ID0 and setting the state information ST[0] to indicate that the IC substrate 710[0] is selectable.

Next, the control circuit 730 can apply the predetermined voltage Vsrc to the voltage divider 724. In a case where the predetermined voltage Vss is a ground voltage, the voltage level V(i) at the node N[i] in the IC substrate 710[i] (i=0, 1, . . . , N) is equal to (or substantially equal to) VLsrc×(i/N), where VLsrc represents the voltage level of the predetermined voltage Vsrc.

For example, the control circuit 730 can apply the predetermined voltage Vsrc to one end of the conductive path 722 located at the IC substrate 710[N], while the other end of the conductive path 722 located at the IC substrate 710[0] is coupled to the ground voltage. The voltage level at the first input terminal of the comparator 716[i] (coupled to the node N[i]) is equal to or substantially equal to VLsrc×(i/N).

In addition, the control circuit 730 can set the voltage level VLref of the reference voltage Vref to be between V(1) and V(2), and apply the reference voltage Vref to the second input terminal of each comparator. The comparator 716[i] (i=0, 1, . . . , N) is configured to compare the voltage level V(i) with the voltage level VLref. When a comparison result of a comparator indicates that the voltage level VLref is greater than the voltage level V(i), and an IC substrate corresponding to the comparator is in a non-selectable state, the control circuit 730 can set that IC substrate to a selectable state and assign the data ID1 to an identifier of the IC substrate.

For example, the comparison result of comparator 716[1] may indicate that the voltage level VLref is greater than the voltage level V(1), and the IC substrate 710[1] is in a non-selectable state. The control circuit 730 can be configured to set the state information ST[1] to indicate that the IC substrate 710[1] is selectable, and set the identifier ID[1] as the data ID1 (e.g., the data ID0 plus a predetermined value or address offset).

After the identifier ID[1] is generated, the control circuit 730 can set the voltage level VLref of the reference voltage Vref to be between V(2) and V(3), and apply the reference voltage Vref to the second input terminal of each comparator. Similarly, the comparator 716[i] (i=0, 1, . . . , N) is configured to compare the voltage level V(i) with the voltage level VLref. When a comparison result of a comparator indicates that the voltage level VLref is greater than the voltage level V(i), and an IC substrate corresponding to the comparator is in a non-selectable state, the control circuit 730 can set that IC substrate to a selectable state and assign the data ID2 to an identifier of the IC substrate

For example, the comparison result of comparator 716[2] may indicate that the voltage level VLref is greater than the voltage level V(2), and the IC substrate 710[2] is in a non-selectable state. The control circuit 730 can be configured to set the state information ST[2] to indicate that the IC substrate 710[2] is selectable, and set the identifier ID[2] as the data ID2 (e.g., the data ID1 plus a predetermined value or address offset).

After the respective identifiers ID[0]-ID[N] have been stored in the IC substrates 710[0]-710[N], the control circuit 730 can individually select the IC substrates 710[0]-710[N] according to the identifiers ID[0]-ID[N].

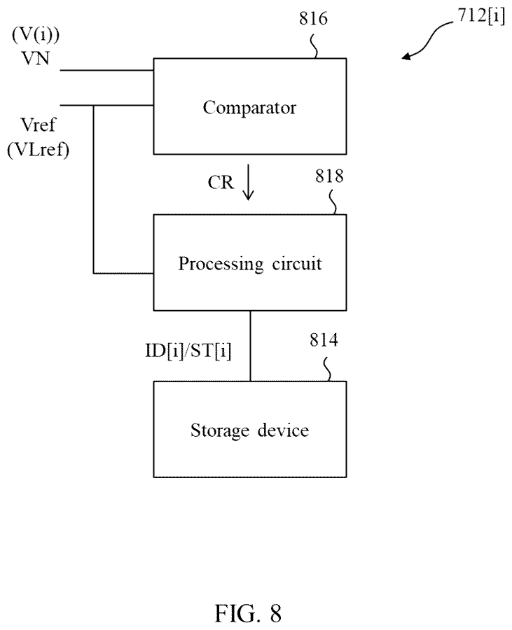

FIG. 8 illustrates an implementation of the identification circuit 712[i] (i=0, 1, . . . , N) shown in FIG. 7 in accordance with some embodiments of the present disclosure. The identification circuit 712[i] can include, but is not limited to, a storage device 814, a comparator 816 and a processing circuit 818. The storage device 814 is configured to store the state information ST[i] and the identifier ID[i] of the IC substrate 710[i] shown in FIG. 7. The storage device 814 can be implemented using volatile or non-volatile storage devices. The comparator 816 is configured to compare the reference voltage Vref (having the voltage level VLref) with the node voltage VN (having the voltage level V(i)) to generate the comparison result CR. The processing circuit 818 is coupled to the storage device 814 and the comparator 816. When the comparison result CR indicates that the voltage level VLref is greater than the voltage level V(i), and the state information ST[i] indicates a non-selectable state, the processing circuit 818 is configured to refer to the voltage level VLref to generate the identifier ID[i], and update the state information ST[i] to indicate a selectable state. When the comparison result CR indicates that the voltage level VLref is less than the voltage level V(i), or that the state information ST[i] indicates a selectable state, the processing circuit 818 will not change the identifier ID[i] and the state information ST[i].

Consider an example where the identification circuit 712[1] shown in FIG. 7 is implemented using the architecture shown in FIG. 8 (i.e. i=1). Referring to FIG. 8 and also to FIG. 7, when the control circuit 730 is configured to set the voltage level VLref of the reference voltage Vref to be between V(1) and V(2), the comparison result CR generated by the comparator 816 indicates that the voltage level VLref is greater than the voltage level V(1). The processing circuit 818 can read the state information ST[1] from the storage device 814, in which the state information ST[1] indicates a non-selectable state. The processing circuit 818 can generate the identifier ID[1] according to the voltage level VLref, and update the state information ST[1] to indicate a selectable state. Note that when the control circuit 730 is configured to set the voltage level VLref of the reference voltage Vref to be between V(2) and V(3), the comparison result CR generated in the identification circuit 712[1] indicates that the voltage level VLref is greater than the voltage level V(1). As the state information ST[1] read from the storage device 814 indicates a selectable state, the processing circuit 818 will not change the identifier ID[1] and the state information ST[1].

As those skilled in the art can appreciate that the architecture shown in FIG. 8 can be applied to each identification circuit shown in FIG. 7, similar description is omitted here for brevity.

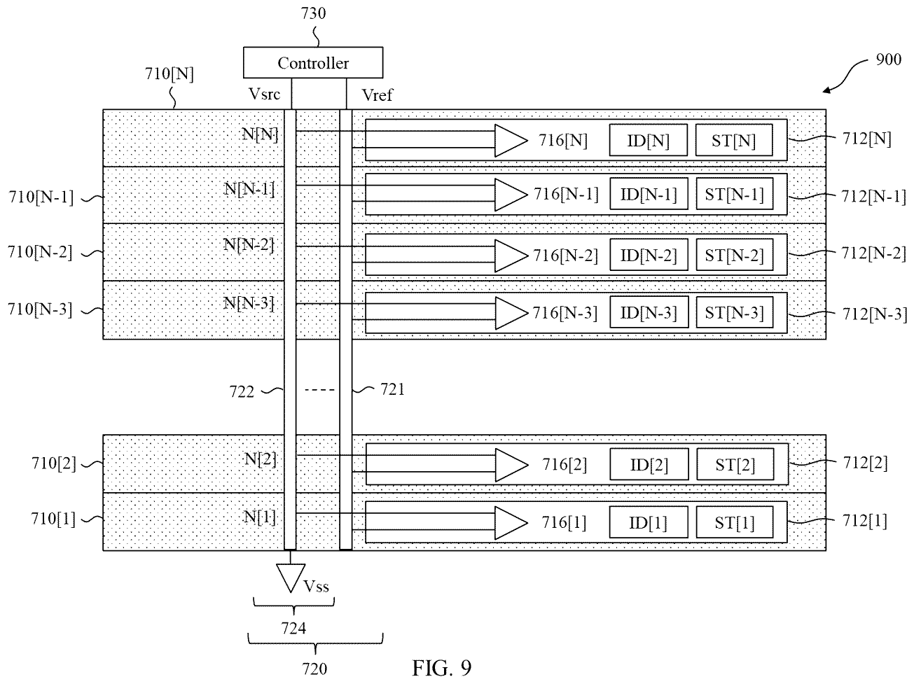

FIG. 9 is a diagram illustrating another implementation of the semiconductor package 100 shown in FIG. 1 in accordance with some embodiments of the present disclosure. The structure of the semiconductor package 900 is substantially identical to that of the semiconductor package 700 shown in FIG. 7 except that the stacked IC substrates of the semiconductor package 900 are implemented as identical layers. In the present embodiment, the semiconductor package 900 includes the IC substrates 710[1]-710[N] and the conductive structure 720 shown in FIG. 7.

In operation, the control circuit 730 may firstly reset the IC substrates 710[2]-710[N] to a non-selectable state, and set the identifier ID[1] of the IC substrate 710[1] as the data ID1, making set the IC substrate 710[1] selectable.

For example, the control circuit 730 can set the state information ST[2]-ST[N] to indicate that the IC substrates 710[2]-710[N] are non-selectable. In addition, the control circuit 730 can assign an address signal indicative of the data ID1 to the identification circuit 712[1], thereby setting the identifier ID[1] as the data ID1 and setting the state information ST[1] to indicate that the IC substrate 710[1] is selectable.

Next, the control circuit 730 can apply the predetermined voltage Vsrc to the voltage divider 724. In a case where the predetermined voltage Vss is a ground voltage, the voltage level V(i) at the node N[i] in the IC substrate 710[i] (i=1, 2, . . . , N) is equal to (or substantially equal to) VLsrc×((i−1)/(N−1)), where VLsrc represents the voltage level of the predetermined voltage Vsrc.

For example, the control circuit 730 can apply the predetermined voltage Vsrc to one end of the conductive path 722 located at the IC substrate 710[N], while the other end of the conductive path 722 located at the IC substrate 710[1] is coupled to the ground voltage. The voltage level at the first input terminal of the comparator 716[i] (coupled to the node N[i]) is equal to or substantially equal to VLsrc×((i−1)/(N−1)).

In addition, the control circuit 730 can set the voltage level VLref of the reference voltage Vref to be between V(2) and V(3), and apply the reference voltage Vref to the second input terminal of each comparator. The comparator 716[i] (i=1, 2, . . . , N) is configured to compare the voltage level V(i) with the voltage level VLref. When a comparison result of a comparator indicates that the voltage level VLref is greater than the voltage level V(i), and an IC substrate corresponding to the comparator is in a non-selectable state, the control circuit 730 can set that IC substrate to a selectable state and assign the data ID2 to an identifier of the IC substrate.

For example, the comparison result of comparator 716[2] may indicate that the voltage level VLref is greater than the voltage level V(2), and the IC substrate 710[2] is in a non-selectable state. The control circuit 730 can be configured to set the state information ST[2] to indicate that the IC substrate 710[2] is selectable, and set the identifier ID[2] as the data ID2 (e.g., the data ID1 plus a predetermined value or address offset).

As those skilled in the art can appreciate that the operation of the semiconductor package 900 after reading the above paragraphs directed to FIG. 1 to FIG. 8, further description is omitted here for brevity.

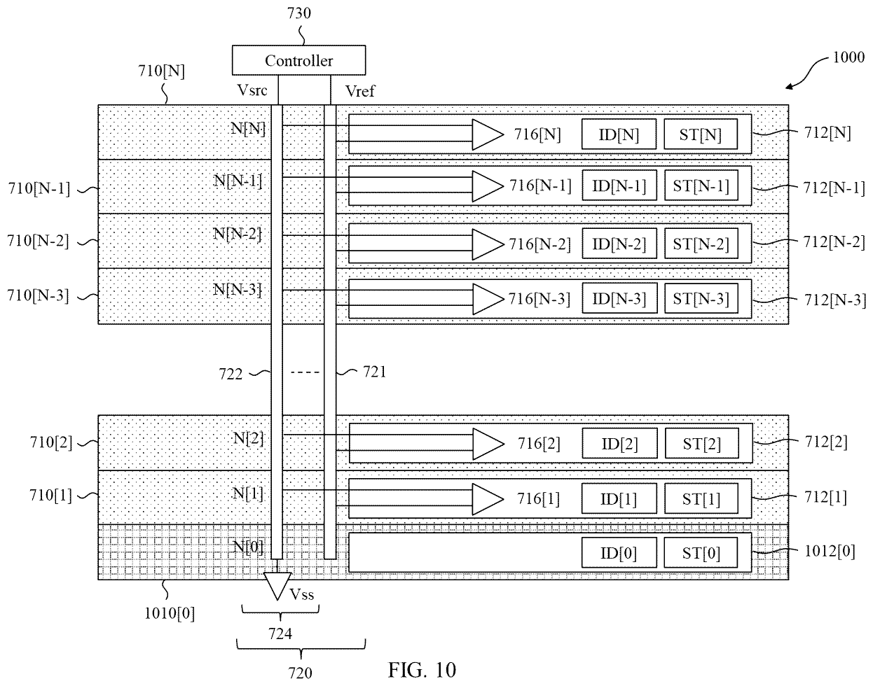

In some embodiments, the comparator of the IC substrate that is assigned an identifier first may be optional. FIG. 10 is a diagram illustrating another implementation of the semiconductor package 100 shown in FIG. 1 in accordance with some embodiments of the present disclosure. The structure of semiconductor package 1000 is substantially identical to that of semiconductor package 700 shown in FIG. 7 except for the IC substrate 1010 [0].

In the present embodiment, the semiconductor package 1000 includes the IC substrates 710[1]-710[N] and the conductive structure 720 shown in FIG. 7. The structure of the identification circuit 1012 [0] can be substantially identical to that of the identification circuit 712[0] except that a comparator is omitted. In operation, the control circuit 730 may firstly reset the IC substrates 710[1]-710[N] to a non-selectable state, and set the identifier ID[0] of the IC substrate 1010 [0] as the data ID0, making set the IC substrate 1010 [0] selectable. Next, the control circuit 730 can apply the predetermined voltage Vsrc to the voltage divider 724 to generate the identifiers of other IC substrates. As those skilled in the art can appreciate that the operation of the semiconductor package 1000 after reading the above paragraphs directed to FIG. 1 to FIG. 9, further description is omitted here for brevity.

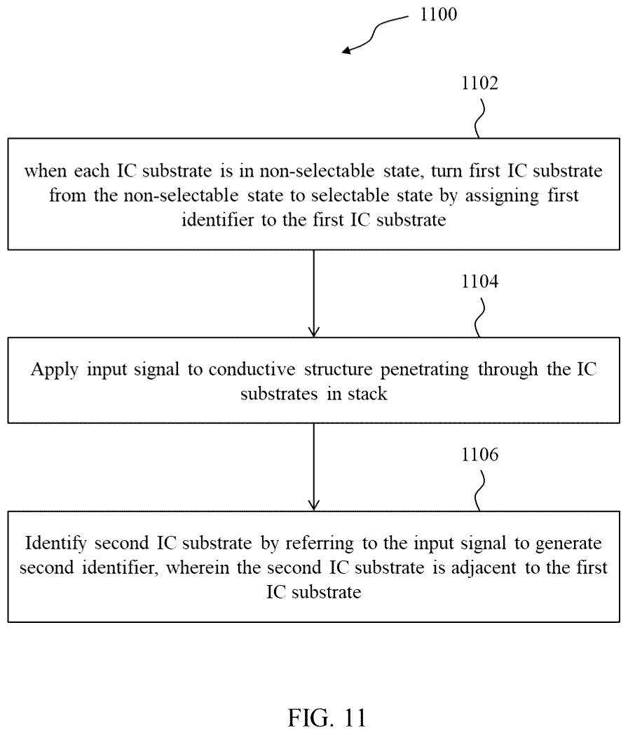

FIG. 11 is a flow chart of an exemplary method for identifying IC substrates in a stack in accordance with some embodiments of the present disclosure. For illustrative purposes, the method 1100 is described below with reference to the semiconductor package 400 and the control circuit 430 shown in FIG. 4. Note that the method 1100 can be applied to other control circuits for identifying stacked IC substrates without departing from the scope of the present disclosure. Additionally, in some embodiments, other operations in the method 1100 can be performed. In some other embodiments, operations of the method 1100 can be performed in a different order and/or vary.

Referring to FIG. 11 and also to FIG. 4, at operation 1102, when each of the IC substrates is in a non-selectable state, a first identifier is assigned to a first IC substrate to thereby turn the first IC substrate from the non-selectable state to a selectable state. For example, the control circuit 430 can turn the IC substrate 410[0] from a non-selectable state to a selectable state by assigning the identifier ID[0] to the IC substrate 410[0].

At operation 1104, an input signal is applied to a conductive structure penetrating through the IC substrates in the stack. For example, the control circuit 430 can apply the input signal S_{IN} to the conductive structure 420 shared by the IC substrates 410[0]-410[N].

At operation 1106, a second IC substrate is identified by referring to the input signal to generate a second identifier. The second IC substrate is adjacent to the first IC substrate. For example, the control circuit 430 can identify the IC substrate 410[1], which is in a non-selectable state or has not been identified, by referring to the input signal S_{IN} to generate the identifier ID[1].

In some embodiments, when the input signal S_{IN} indicates an address that corresponds to the identifier ID[0], the control circuit 430 can select the IC substrate 410[0] according to the input signal S_{IN}, thereby enabling the IC substrate 410[0] to send the stimulus signal SS[0] to the IC substrate 410[1] via wireless coupling, such as inductive or capacitive coupling. The IC substrate 410[1] can be enabled to receive the stimulus signal SS[0] to generate the identifier ID[1].

Note that the method 1100 can be applied to a chip/wafer identification scheme utilizing voltage division. For example, in the embodiment shown in FIG. 7, the control circuit 730 can turn the IC substrate 710[0] from a non-selectable state to a selectable state (operation 1102), apply the reference voltage Vref to the conductive structure 720 (operation 1104), and identify the IC substrate 710[1] by referring to the reference voltage Vref to generate the identifier ID[1] (operation 1106).

In some embodiments, the method 1100 can be applied to wafer level testing. For example, in the embodiment shown in FIG. 3C, the tester 302 can employ the method 1100 shown in FIG. 11 to resister the IC substrates 110[0]-110[P] with their unique identifiers ID[0]-ID[P]. the tester 302 can store the identifiers ID[0]-ID[P], which can be loaded upon the next power-up. As those skilled in the art can appreciate that the operation of the method 1100 after reading the above paragraphs directed to FIG. 1 to FIG. 10, further description is omitted here for brevity.

With the use of the proposed identification scheme, each layer in a chip/wafer stack can be assigned a unique identifier according to a physical spatial relationship between the stacked layers. The proposed identification scheme can individually identify the stacked layers according to their identifiers, thereby ensuring correct implementation of system functions and realizing precise testing and failure analysis.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a plurality of integrated circuit (IC) substrates stacked one above another; and
a conductive structure penetrating through the IC substrates, wherein each of the IC substrates comprises an identification circuit coupled to the conductive structure, and each identification circuit is configured to identify a corresponding IC substrate by receiving an input signal from the conductive structure and accordingly generating an identifier of the corresponding IC substrate.

2. The semiconductor package of claim 1, wherein respective identification circuits of the IC substrates are configured to generate respective identifiers sequentially in a spatial arrangement order of the IC substrates.

3. The semiconductor package of claim 1, wherein the IC substrates comprises:
a first IC substrate, wherein when the input signal indicates an address corresponding to the identifier of the first IC substrate, the identification circuit of the first IC substrate is configured to send a stimulus signal when receiving the input signal; and
a second IC substrate adjacent to the first IC substrate, the identification circuit of the second IC substrate is configured to receive the stimulus signal and generate the identifier of the second IC substrate.

4. The semiconductor package of claim 3, wherein the identification circuit of the first IC substrate comprises a first coupling circuit, and the identification circuit of the second IC substrate comprises a second coupling circuit; the stimulus signal is sent from the first IC substrate to the second IC substrate via wireless coupling between the first coupling circuit and the second coupling circuit.

5. The semiconductor package of claim 4, wherein each of the first coupling circuit and the second coupling circuit is an inductive coupling circuit or a capacitive coupling circuit.

6. The semiconductor package of claim 3, wherein the identification circuit of the first IC substrate comprises:
a storage device, configured to store the identifier of the first IC substrate;
a coupling circuit, configured to generate the stimulus signal according to a drive signal; and
a processing circuit, coupled to the storage device and the coupling circuit, the processing circuit being configured to generate the drive signal by determining whether the input signal indicates the address corresponding to the identifier of the first IC substrate.

7. The semiconductor package of claim 3, wherein the identification circuit of the second IC substrate is configured to generate the identifier of the second IC substrate in response to the stimulus signal when the second IC substrate has not been identified, and the identifier of the second IC substrate is not modified by the stimulus signal when the second IC substrate has been identified.

8. The semiconductor package of claim 3, wherein the identification circuit of the second IC substrate comprises:
a storage device, configured to store state information indicative of whether the second IC substrate has been identified;
a coupling circuit, configured to generate an induced signal according to the stimulus signal; and
a processing circuit, coupled to the storage device and the coupling circuit, wherein when the state information indicates that second IC substrate has not been identified, the processing circuit is configured to receive the induced signal, and refer to the input signal to generate the identifier of the second IC substrate.

9. The semiconductor package of claim 1, wherein the conductive structure comprises:
a first conductive path penetrating through the IC substrates, wherein the input signal is a reference voltage applied to the first conductive path; and
a second conductive path penetrating through the IC substrates, wherein two ends of the second conductive path are connected to different electric potentials to form a voltage divider with nodes, and a segment of the second conductive path between two adjacent nodes serves as a resistive element in the voltage divider;
wherein the identification circuits of the IC substrates are coupled to the nodes respectively; the identification circuit is configured to determine the identifier of the corresponding IC substrate by comparing the reference voltage with a node voltage at a corresponding node.

10. The semiconductor package of claim 9, wherein the identification circuit comprises:
a comparator, configured to compare the reference voltage with the node voltage to generate a comparison result; and
a processing circuit, coupled to the comparator, the processing circuit is configured to generate the identifier of the corresponding IC substrate according to the comparison result.

11. The semiconductor package of claim 1, wherein the IC substrates comprises:
a first IC substrate; and
a plurality of second IC substrates identical to each other, each second IC substrate being non-identical to the first IC substrate, wherein the identification circuit of the first IC substrate is configured to identify the identifier of the first IC substrate before any of the second IC substrates is identified.

12. The semiconductor package of claim 1, further comprising:
a control circuit, coupled to the conductive structure, the control circuit being configured to send the input signal to the conductive structure, wherein the control circuit is located in one of the IC substrates, or located outside the IC substrates.

13. The semiconductor package of claim 1, wherein each of the IC substrates is dynamic random-access memory.

14. The semiconductor package of claim 1, wherein the IC substrates are identical to each other.

15. The semiconductor package of claim 1, wherein at least one of the IC substrates is non-identical to the other IC substrates.

16. A method for identifying integrated circuit (IC) substrates in a stack, comprising:
when each of the IC substrates is in a non-selectable state, turning a first IC substrate of the IC substrates from the non-selectable state to a selectable state by assigning a first identifier to the first IC substrate;
applying an input signal to a conductive structure penetrating through the IC substrates in the stack; and
identifying a second IC substrate of the IC substrates by referring the input signal and generating a second identifier, wherein the second IC substrate is adjacent to the first IC substrate.

17. The method of claim 16, wherein the input signal indicates an address corresponding to the first identifier; the step of identifying the second IC substrate by referring to the input signal to generate the second identifier comprises:
selecting the first IC substrate according to the input signal, thereby enabling the first IC substrate to send a stimulus signal to the second IC substrate via wireless coupling; and
enabling the second IC substrate to receive the stimulus signal to generate the second identifier.

18. The method of claim 17, wherein the wireless coupling is inductive coupling or capacitive coupling.

19. The method of claim 16, wherein the input signal is a reference voltage applied to a first conductive path of the conductive structure; two ends of a second conductive path of the conductive structure are connected to different electric potentials to form a voltage divider with nodes, and a segment of the second conductive path between two adjacent nodes serves as a resistive element in the voltage divider; the step of identifying the second IC substrate by referring to the input signal to generate the second identifier comprises:
enabling the second IC substrate to compare the reference voltage with a node voltage at a corresponding node in the second IC substrate, thereby generating the second identifier.

20. The method of claim 16, further comprising:
when the second identifier of the second IC substrate is generated, setting the second IC substrate to the selectable state.
